(19) United States
(12) Patent Application Publication
(10) Pub. No.: US 2011/0198034 A1
(43) Pub. Date: Aug. 18, 2011

(54) GAS DISTRIBUTION SHOWERHEAD WITH COATING MATERIAL FOR SEMICONDUCTOR PROCESSING

(76) Inventors: Jennifer Sun, Mountain View, CA (US); Senh Thach, Union City, CA (US); Ren-Guan Duan, Fremont, CA (US); Thomas Graves, Los Altos, CA (US)

(21) Appl. No.: 13/011,839

(22) Filed: Jan. 21, 2011

Related U.S. Application Data
(60) Provisional application No. 61/303,609, filed on Feb. 11, 2010.

(51) Int. Cl. H01L 21/00; C23C 4/12; C23C 16/455; C23C 16/50; C23F 1/08

(52) U.S. Cl. 156/345.34; 427/446; 118/715; 118/723 R

(57) ABSTRACT

Described herein are exemplary methods and apparatuses for fabricating a gas distribution showerhead assembly in accordance with one embodiment. In one embodiment, a method includes providing a gas distribution plate having a first set of through-holes for delivering processing gases into a semiconductor processing chamber. The first set of through-holes is located on a backside of the plate (e.g., Aluminum substrate). The method includes spraying (e.g., plasma spraying) a coating material (e.g., Ytrria based material) onto a cleaned surface of the gas distribution plate. The method includes removing (e.g., surface grinding) a portion of the coating material from the surface to reduce a thickness of the coating material. The method includes forming (e.g., UV laser drilling, machining) a second set of through-holes in the coating material such that the through-holes are aligned with the first-set of through-holes.

### RELATED APPLICATION

This application claims the benefit of U.S. Provisional Application Ser. No. 61/303609, filed on Feb. 11, 2010 the entire contents of which are incorporated by reference.

### TECHNICAL FIELD

Embodiments of the present invention relate to a gas distribution showerhead having a coating material.

### BACKGROUND

Semiconductor manufacturing processes utilize a wide variety of gases, such as fluorine-based gases, chlorine-based gases, silanes, oxygen, nitrogen, organic gases (such as hydrocarbons and fluorocarbons), and noble gases (such as argon or helium). In order to provide uniform distribution of processing gases into a semiconductor processing chamber (such as an etch chamber or a deposition chamber), a “showerhead” type gas distribution assembly has been adopted as a standard in the semiconductor manufacturing industry.

As semiconductor processing adopts more aggressive process regimes such as very high power chambers or Hydrogen containing chemistries, existing showerhead assemblies reach their manufacturing limits. Typical problems of current showerhead approaches include shorter lifetime because the Silicon Carbide (SiC) plate erosion is accelerated with an aggressive process. Also, current showerhead material does not allow Chlorine chemistry insitu dry-clean for Aluminum-Fluoride byproduct removal. Additionally, current designs that have the showerhead bonded to the electrode have an inherent out-of-flat issue, which impedes the showerhead's thermal performance.

### SUMMARY

Described herein are exemplary methods and apparatuses for fabricating a gas distribution showerhead assembly in accordance with one embodiment. In one embodiment, a method includes providing a gas distribution plate having a first set of through-holes for delivering processing gases into a semiconductor processing chamber. The first set of through-holes is located on a backside of the plate (e.g., Aluminum substrate). The method includes spraying (e.g., plasma spraying) a coating material (e.g., Ytrria based material) onto a cleaned surface of the gas distribution plate. The method includes removing (e.g., surface grinding) a portion of the coating material from the surface to reduce a thickness of the coating material. The method includes forming (e.g., UV laser drilling, machining) a second set of through-holes in the coating material such that the through-holes are aligned with the first-set of through-holes.

### BRIEF DESCRIPTION OF THE DRAWINGS

Embodiments of the present invention are illustrated by way of example, and not by way of limitation, in the figures of the accompanying drawings and in which:

FIG. 1 illustrates one embodiment of a method for fabricating a gas distribution showerhead assembly;

FIGS. 2A-2C illustrate cross-sectional views of a gas distribution showerhead assembly for use within a semiconductor processing chamber in accordance with one embodiment;

FIG. 3 shows a top view of a gas distribution plate in accordance with one embodiment;

FIG. 4 illustrates a normalized erosion rate for etch chemistries having hydrogen versus etch chemistries that do not have hydrogen in accordance with one embodiment;

FIG. 5 illustrates a normalized erosion rate for etch chemistries having hydrogen versus etch chemistries that do not have hydrogen in accordance with another embodiment;

FIG. 6 illustrates a normalized erosion rate for various types of coating materials in accordance with one embodiment;

FIGS. 7 and 8 illustrate images of a gas distribution plate and coating material in accordance with one embodiment;

FIG. 9 is a substrate processing apparatus in accordance with one embodiment;

FIG. 10 illustrates a cross sectional view of a showerhead assembly according to one embodiment;

FIG. 11 illustrates another embodiment of a cross sectional view of a showerhead assembly; and

FIG. 12 illustrates another embodiment of a method for fabricating a gas distribution showerhead assembly.

### DETAILED DESCRIPTION

Described herein are exemplary methods and apparatuses for fabricating a gas distribution showerhead assembly in accordance with one embodiment. In one embodiment, a method includes providing a gas distribution plate having a first set of through-holes for delivering processing gases into a semiconductor processing chamber. The first set of through-holes is located on a backside of the plate (e.g., Aluminum substrate). The method includes spraying (e.g., plasma spraying) a coating material (e.g., Ytrria based material) onto a cleaned surface of the gas distribution plate. The method includes removing (e.g., surface grinding) a portion of the coating material from the surface to reduce a thickness of the coating material. The method includes forming (e.g., UV laser drilling, machining) a second set of through-holes in the coating material such that the through-holes are aligned with the first-set of through-holes.

The coating materials (e.g., Ytrria based materials, advanced coating material, YAG, etc.) described in the present disclosure can be used to provide lifetime showerhead requirements, low particles, low metallic contaminants, thermal performance requirements, and etch uniformity requirements. These coating materials have enhanced plasma erosion resistance compared to conventional showerhead designs. Additionally, the coating materials and integration process make is feasible for a no-bond showerhead design and also a clamped-on gas distribution plate design for improved thermal performance and showerhead fabrication lead time.

The following description provides details of a showerhead assembly used in manufacturing machines that process substrates and/or wafers to manufacture devices (e.g., electronic devices, semiconductors, substrates, liquid crystal displays, reticles, micro-electro-mechanical systems (MEMS)). Manufacturing such devices generally require dozens of manufacturing steps involving different types of manufacturing processes. For example, etching, sputtering, and chemical vapor deposition are three different types of processes, each of which is performed on different chambers or in the same chamber of a machine.

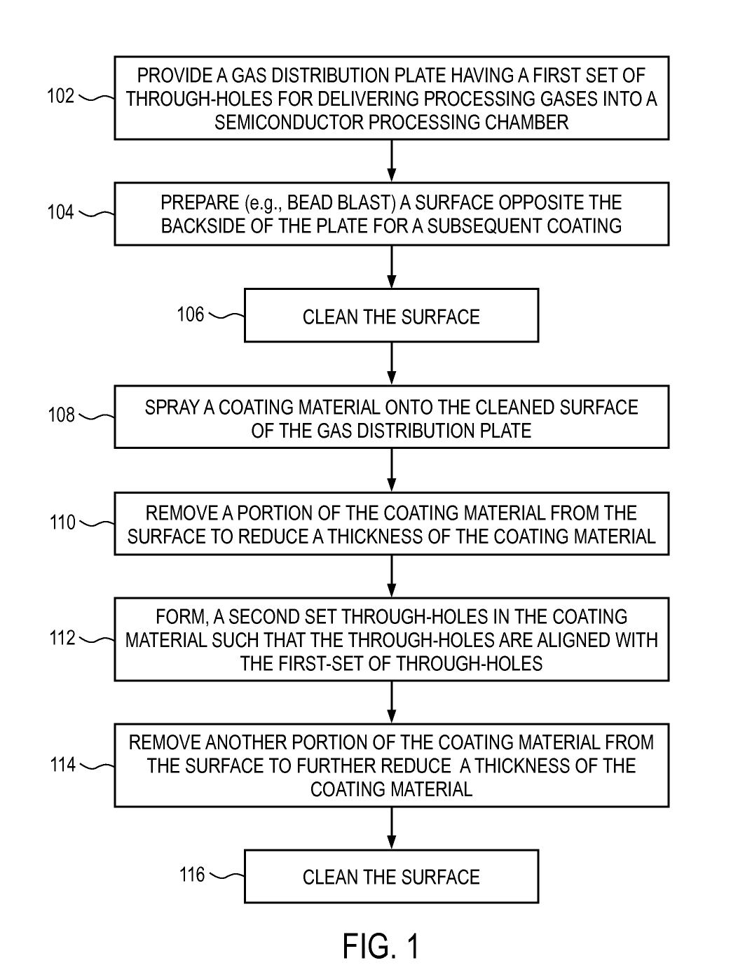

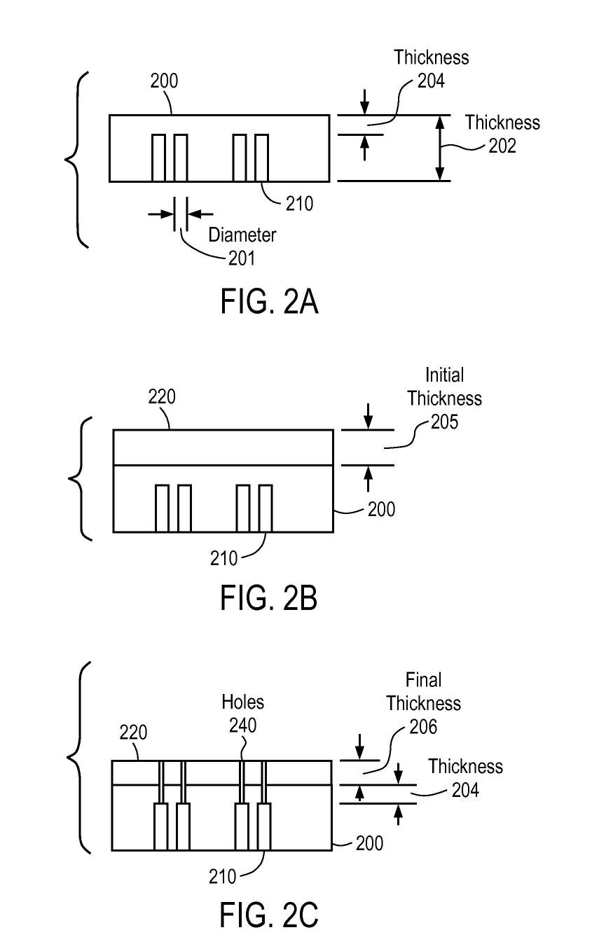

FIG. 1 illustrates one embodiment of a method for fabricating a gas distribution showerhead assembly. The method includes providing a gas distribution plate having a first set of through-holes for delivering processing gases into a semiconductor processing chamber at block 102. The first set of through-holes is located on a backside of the plate (e.g., Aluminum substrate) as illustrated in FIG. 2A. The method includes preparing (e.g., bead blasting, grit blast) a surface opposite the backside of the plate for a subsequent coating at block 104. The surface is cleaned at block 106. The method includes spraying (e.g., plasma spraying) a coating material (e.g., Ytrria based material) onto the cleaned surface of the gas distribution plate at block 108 as illustrated in FIG. 2B. In an embodiment, the coating material is plasma sprayed at an angle of approximately 90 degrees with respect to the surface of the gas distribution plate. The method includes removing (e.g., surface grinding) a portion of the coating material from the surface to reduce a thickness of the coating material at block 110. The method includes forming (e.g., UV laser drilling, gas hole drilling) a second set of through-holes in the coating material such that the through-holes are aligned with the first-set of through-holes at block 112. The method includes removing (e.g., surface grinding) another portion of the coating material from the surface to further reduce a thickness of the coating material at block 114 as illustrated in FIG. 2C. The surface is cleaned at block 116.

The operations of exemplary methods described in the present disclosure can be performed in a different order, sequence, and/or have more or less operations than described. For example, operations 110 or 114 may be optionally performed or removed from the method described above.

FIGS. 2A-2C illustrate cross-sectional views of a gas distribution showerhead assembly for use within a semiconductor processing chamber in accordance with one embodiment. A gas distribution plate 200 has a first set of through-holes 210 for delivering processing gases into the semiconductor processing chamber as illustrated in FIG. 2A. The first set of through-holes has a diameter 201 of approximately 0.070 inches to 0.090 inches (e.g., 0.080 inches). The plate has a total thickness 202 of approximately 0.038 inches to 0.050 inches (e.g., 0.433 inches) and a partial thickness 204 that is adjacent to the holes of approximately 0.015 inches to 0.025 inches (e.g., 0.020 inches).

A coating material 220 is sprayed (e.g., plasma spray) onto the gas distribution plate 200 as illustrated in FIG. 2B with initial thickness 205. In an embodiment, the coating material includes Ytrria. In certain embodiments, the coating material includes at least one of the following materials or combinations of materials: YAG, Y₂O₃/2OZrO₂, Y₂O₃, Al₂O₃/YAG, advanced coating material, Y₂O₃/ZrO₂/Nb₂O₅, ZrO₂/3Y₂O₃, and Y₂O₃/ZrO₂/HfO₂. These coating materials increase erosion resistance compared to conventional showerheads.

The coating material 220 has a second set of through-holes drilled in alignment with the first set of through-holes for delivering processing gases into the semiconductor processing chamber as illustrated in FIG. 2C. The second set of through-holes has a diameter of approximately 0.010 inches to 0.030 inches (e.g., 0.020 inches). The coating material 220 has a final thickness 206 of approximately 0.020 inches to 0.030 inches (e.g., 0.025 inches) after a removal operation discussed in block 114 of FIG. 1. In an embodiment, two of the second set of through-holes 240 are aligned with each through-hole 210 of the first set of through-holes.

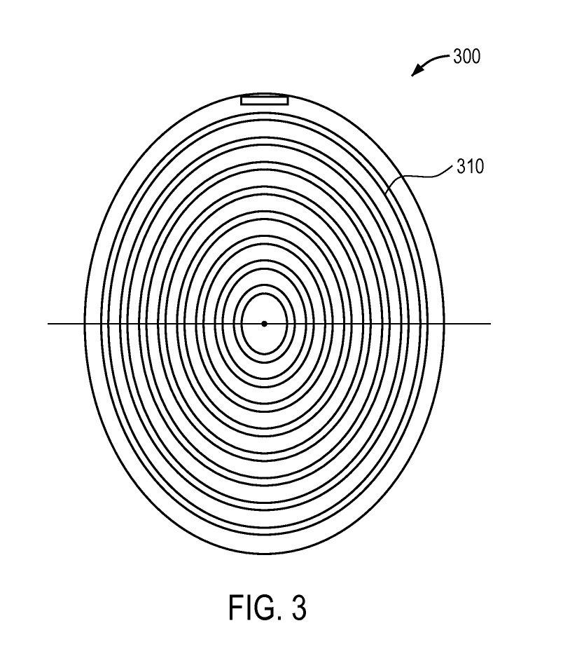

FIG. 3 shows a top view of a gas distribution plate in accordance with one embodiment. The gas distribution plate 300 includes multiple annular rings of through-holes 310 (e.g., through-holes 240), where the spacing between walls of the through-holes is about 0.010 inch. In an embodiment, two annular rings of through-holes 310 are aligned with a ring of counter-bore through-holes 210, which are not shown in FIG. 3.

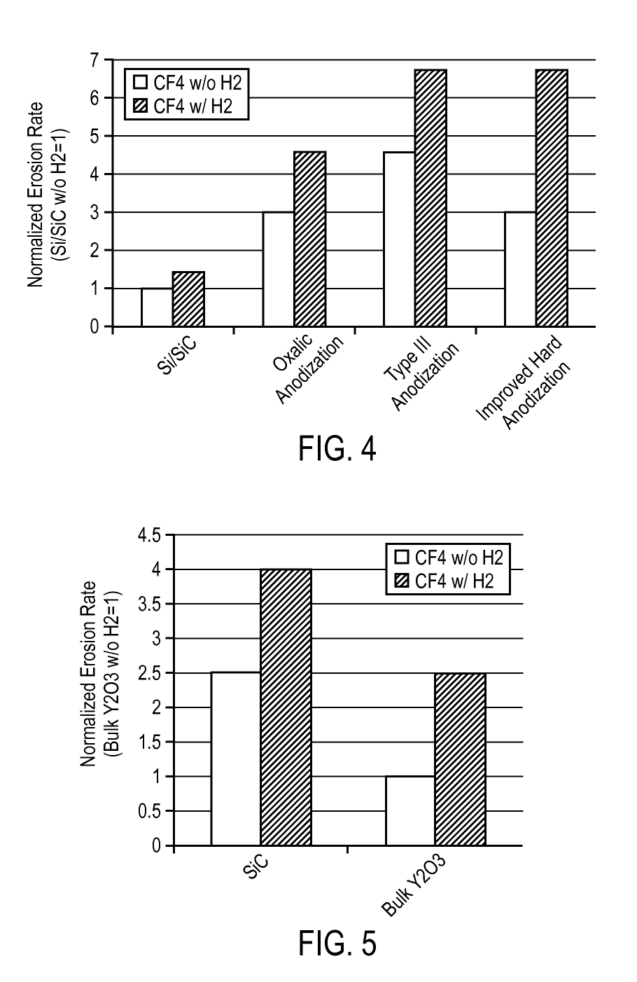

FIG. 4 illustrates a normalized erosion rate for etch chemistries having hydrogen versus etch chemistries that do not have hydrogen in accordance with one embodiment. Si/SiC, oxalic anodization, type III anodization, and hard anodization all have more erosion for chemistries with a hydrogen chemistry as illustrated in FIG. 4.

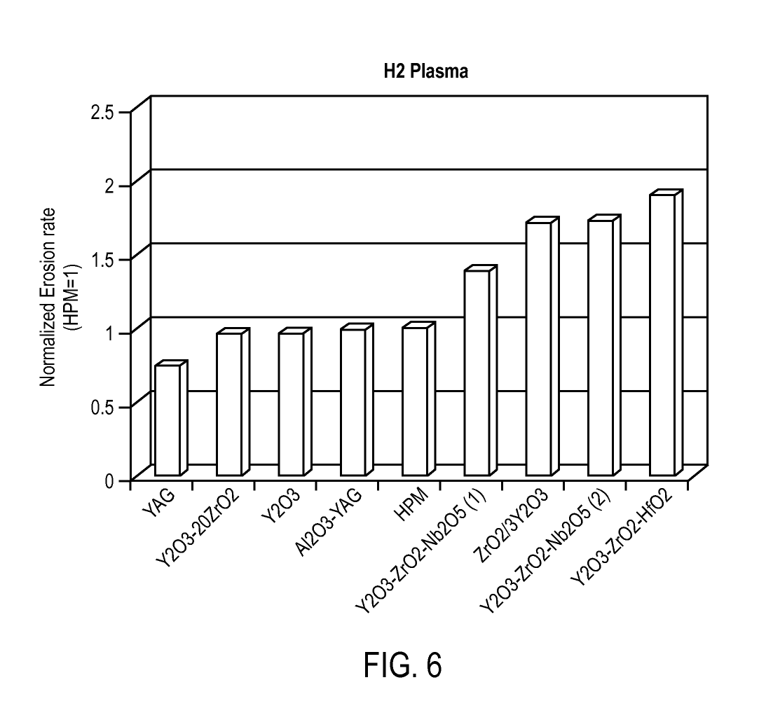

FIG. 5 illustrates a normalized erosion rate for etch chemistries having hydrogen versus etch chemistries that do not have hydrogen in accordance with another embodiment. SiC and Ytrria based materials (e.g., Y2O3) both have more erosion for chemistries with a hydrogen chemistry as illustrated in FIG. 5. However, the Y2O3 material has significantly less erosion than the SiC material for both etch chemistries having hydrogen and those not having hydrogen. Thus, a Ytrria based showerhead has significantly less erosion for etch chemistries with and without hydrogen in comparison to a conventional SiC showerhead.

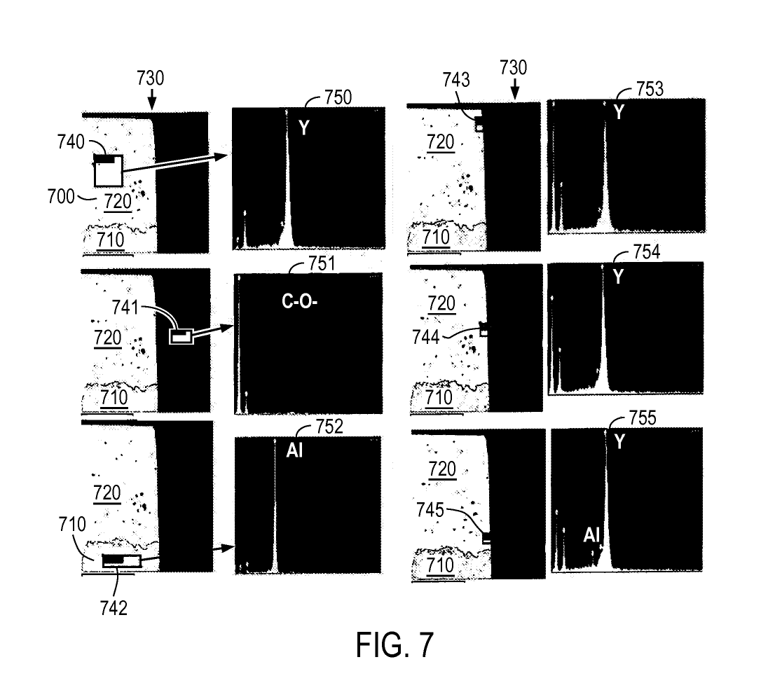

FIG. 6 illustrates a normalized erosion rate for various types of coating materials in accordance with one embodiment. The erosion rates are normalized with respect to an advanced coating material. In an embodiment, the advanced coating material includes YtO3, AlO3, and ZrO3. FIG. 6 illustrates the erosion rate of the following materials or combinations of materials: YAG, Y₂O₃/2OZrO₂, Y₂O₃, Al₂O₃/YAG, an advanced coating material (e.g., HPM), Y₂O₃/ZrO₂/Nb₂O₅, ZrO₂/3Y₂O₃, and Y₂O₃/ZrO₂/HfO₂. These coating materials may have the following composition.
Y2O3-20ZrO2: 80 wt % Y2O3, 20 wt % ZrO2
Al2O3-YAG: 70 wt % Al2O3 and 30 wt % YAG
HPM: 70 wt % Y2O3, 20 wt % ZrO2 and 10 wt % Al2O3
Y2O3-ZrO2-Nb2O5 (1): 70 wt % Y2O3, 20 wt % ZrO2, and 10 wt % Nb2O5
ZrO2/3Y2O3: 97 wt % ZrO2 and 3 wt % Y2O3
Y2O3-ZrO2-Nb2O5 (2): 60 wt % Y2O3, 20 wt % ZrO2, and 20 wt % Nb2O5
Y2O3-ZrO2-HfO2: 70 wt % Y2O3, 20 wt % ZrO2, and 10 wt % HfO2
   These coating materials increase erosion resistance compared to conventional showerheads. For a general etch chemistry not having hydrogen, any of the coating materials illustrated in FIG. 6 will work well for erosion resistance. For an etch chemistry with hydrogen, the coating materials with YAG, Y₂O₃/2OZrO₂, Y₂O₃, Al₂O₃/YAG, advanced coating material, Y₂O₃/ZrO₂/Nb₂O₅ have lowest erosion rate. The coating materials illustrated in FIG. 6 can be used to provide lifetime showerhead requirements, low particles, low metallic contaminants, thermal performance requirements, and etch uniformity requirements.

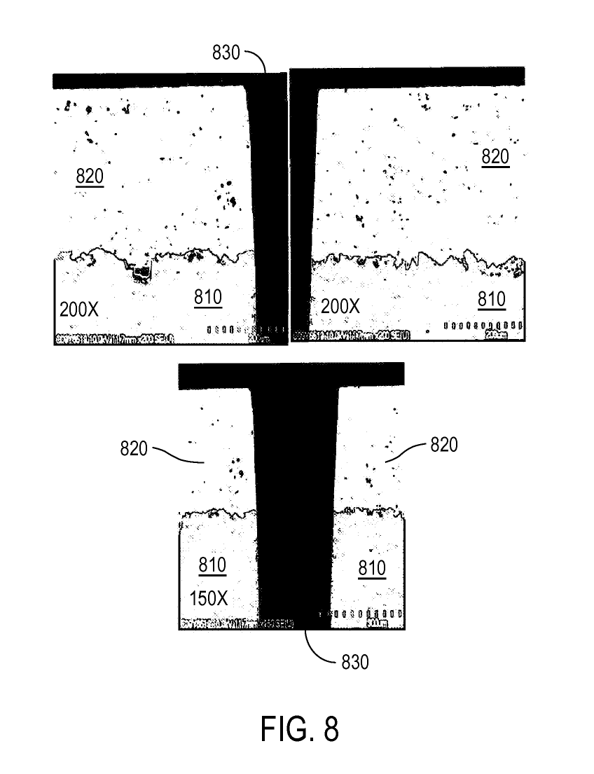

FIGS. 7 and 8 illustrate images of a gas distribution plate and coating material in accordance with one embodiment. The image 700 is repeated six times in FIG. 7 with each image including a Aluminum plate 710, a plasma coating material 720, a laser drilled hole 730, an analysis box (e.g., 740-745). An UV drilled type EDX analysis image 750-755 corresponds to the analysis boxes 740-745. For example, box 740 located in the bulk of the plasma coating material 720 corresponds to the EDX analysis image 750. Image 750 illustrates the materials found in the box 740. No Aluminum from the Aluminum plate 710 is found in the images 750, 751, 753, and 754, which correspond to regions within the plasma coating material or within the hole 730. Aluminum is found in image 752, which corresponds to a box 742 that is located in the Aluminum plate 710. A small Aluminum peak is found on image 755, which corresponds to box 745 that is located in the drilled hole near the Aluminum plate.

FIG. 8 illustrates images of the Aluminum plate 810, coating material 820, and laser drilled hole 830 in accordance with one embodiment. FIG. 8 illustrates that there is no loosely held plasma spray coating and no coating delamination at the coating material/Aluminum plate interface with the hole edge.

The laser drilling process (e.g., UV drilled) described above produces a clean hole. The process does not cross-contaminant the coating material with substrate plate material as illustrated in FIGS. 7 and 8. This fabrication process provides robust on-substrate particle and contamination performance.

The showerheads discussed above are suitable for integration with semiconductor apparatuses that are used for processing substrates such as semiconductor substrates 908, and may be adapted by those of ordinary skill to process other substrates such as flat panel displays, polymer panels or other electrical circuit receiving structures. Thus, the apparatus 900 should not be used to limit the scope of the invention, nor its equivalents, to the exemplary embodiments provided herein.

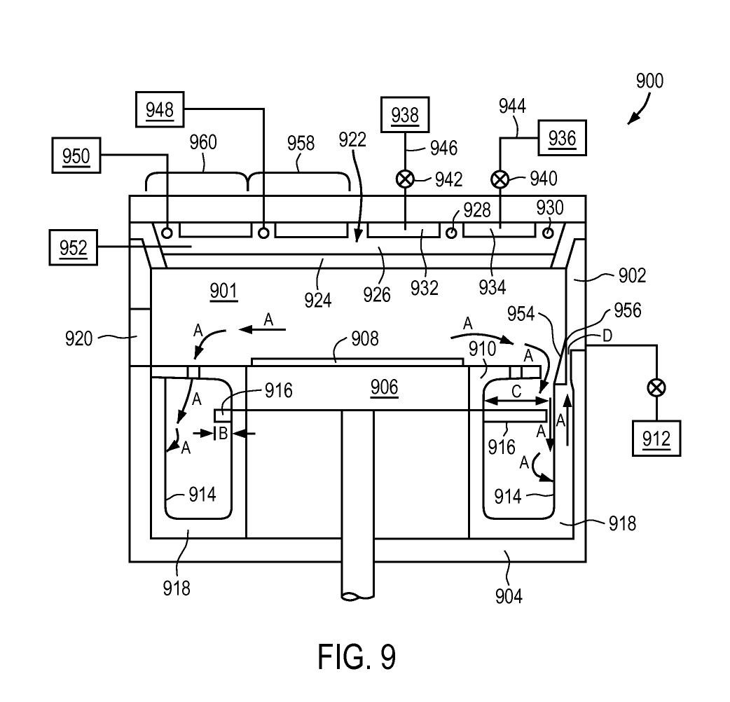

An embodiment of an apparatus 900 suitable for processing substrates according to the processes described herein, is shown in FIG. 9. The apparatus 900 includes a chamber 901 having a plurality of walls 902 extending upwards from a chamber bottom 904. Within the chamber 901, a susceptor 906 is present upon which a substrate 908 may be supported for processing. The substrate 908 may be introduced into the chamber 901 through a slit valve opening 920.

The chamber 901 may be evacuated by a vacuum pump 912 coupled to the chamber wall 902 through a vacuum port 956. The chamber 901 may be evacuated by drawing the processing gas around and through a baffle 910 that circumscribes the susceptor 906 and substrate 908. The further away from the vacuum pump 912, the less the draw of the vacuum may be detected. Conversely, the closer to the vacuum pump 912, the greater the draw of the vacuum that may be detected. Thus, to compensate for an uneven vacuum draw, a flow equalizer 916 may be disposed within the chamber 901. The flow equalizer 916 may circumscribe the susceptor 906. The width of the flow equalizer 916 may be smaller at the location further away from the vacuum port 956 as shown by arrows “B” compared to the width of the flow equalizer 916 at a location closest to the vacuum port 956 as shown by arrows “C”. The gas being evacuated may flow around the flow equalizer and then through a lower liner 914. The lower liner 914 may have one or more holes therethrough to permit the processing gas to be evacuated therethrough. A space 918 is present between the lower liner 914 and the walls 902 of the chamber 901 to permit the gas to flow behind the lower liner 914 to the vacuum port 956. The vacuum port 956 may be blocked by a flow blocker 954 to prevent processing gas from being drawn directly into the vacuum pump 912 from an area close to the substrate 908. The evacuated gas may flow along a path shown by arrows “A”.

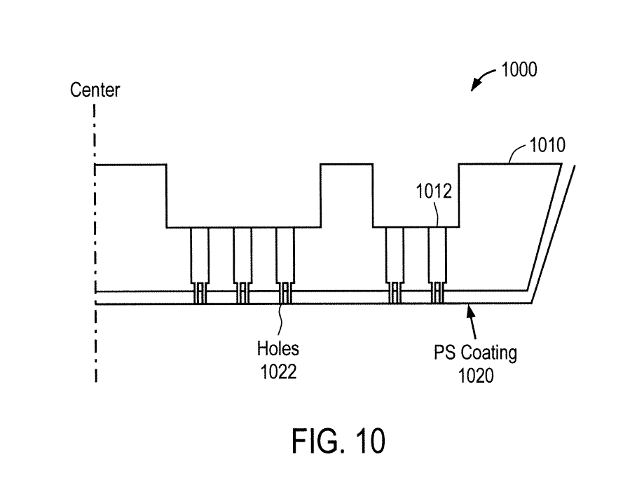

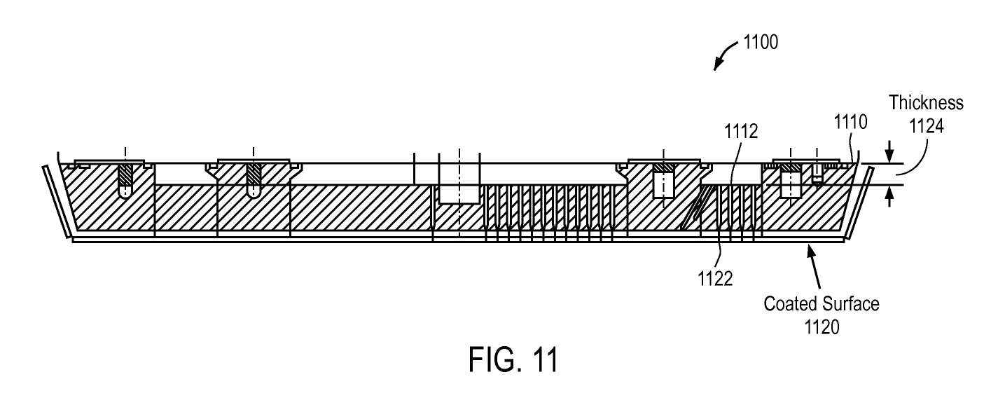

Processing gas may be introduced into the processing chamber 901 through a showerhead 922. The showerhead 922 may be biased by an RF current from an RF power source 952, and the showerhead 922 may include a diffuser plate 926 and a coating material 924. The coating material 924 is shown coated on a lower surface of the plate 926. It may also be coated on other surfaces (e.g. side surfaces) of the plate 926 as illustrated in FIGS. 10 and 11. In one embodiment, the diffuser plate 926 may comprise aluminum. The showerhead 922 may be divided into an inner zone 958 and an outer zone 960. The inner zone 958 may have a heating element 928. In one embodiment, the heating element 928 may have an annular shape. The heating element 928 may be coupled with a heating source 948. The outer zone 960 may also include a heating element 930 coupled with a heating source 950. In one embodiment, the heating elements 928, 930 may include annular conduits that are filled with a heating fluid from the heating sources 948, 950. In another embodiment, the heating elements 928, 930 may comprise heating coils powered by the heating sources 948, 950. While not shown, thermocouples may provide real time temperature feedback to a controller that controls the amount of heat supplied to the inner zone 958 and the outer zone 960.

The inner zone 958 may be coupled with a gas source 938 by a conduit 946. Gas from the gas source 938 may flow through the conduit 946 to a plenum 932 disposed behind the diffuser plate 926 of the showerhead 922. A valve 942 may be disposed along the conduit 946 to control the amount of gas that flows from the gas source 938 to the plenum 932. Once the gas enters the plenum 932, the gas may then pass through the diffuser plate 926. Similarly, the outer zone 960 may be coupled with a gas source 938 by a conduit 944. A valve 940 may be disposed along the conduit 944 to control the amount of gas that flows from the gas source 936 to the plenum 934.

It is to be understood that while separate gas sources 936, 938 have been shown in FIG. 1, a single, common gas source may be utilized. When a single common gas source is utilized, separate conduits 944, 946 may be coupled to the gas source and the valves 940, 942 may control the amount of processing gas that reaches the plenums 932, 934.

FIG. 10 illustrates a cross sectional view of a showerhead assembly according to one embodiment. A showerhead assembly 1000 has through-holes 1010 for delivering processing gases into the semiconductor processing chamber. A coating material 1020 is sprayed (e.g., plasma spray) onto the assembly 1000 as illustrated in FIG. 10. In an embodiment, the coating material includes Ytrria. In certain embodiments, the coating material includes any of the materials or combinations of materials disclosed herein. The advanced coating material includes YtO3, AlO3, and ZrO3. The coating material 1020 has through-holes 1022 formed in alignment with through-holes 1012 for delivering processing gases into the semiconductor processing chamber.

FIG. 11 illustrates a cross sectional view of a showerhead assembly according to another embodiment. A showerhead assembly 1100 has through-holes 1112 for delivering processing gases into the semiconductor processing chamber. A coating material 1120 is sprayed (e.g., plasma spray) onto the assembly 1100 as illustrated in FIG. 11. In an embodiment, the coating material includes Ytrria or any of the coating materials or combinations disclosed herein. The coating material 1120 has through-holes 1122 formed in alignment with through-holes 1112 for delivering processing gases into the semiconductor processing chamber. The showerhead assembly has a thickness 1124 between an upper surface of the assembly and one end of holes 1112. The thickness 1124 is approximately 0.050 mm with an approximate range of 0.47 mm-0.52 mm.

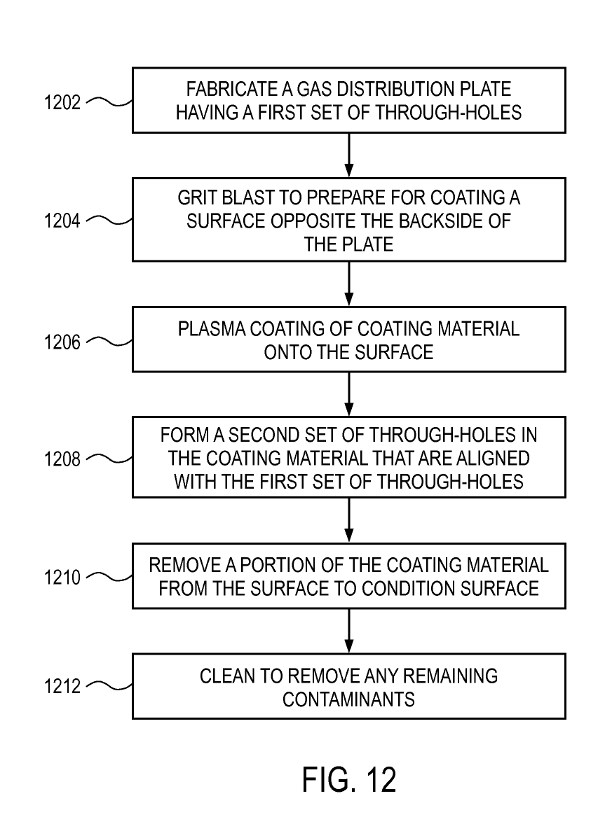

FIG. 12 illustrates another embodiment of a method for fabricating a gas distribution showerhead assembly. The method includes fabricating a gas distribution plate having a first set of through-holes for delivering processing gases into a semiconductor processing chamber at block 1202. The method includes preparing (e.g., grit blasting) a surface opposite the backside of the plate for a subsequent coating at block 1204. The surface may be optionally cleaned. The method includes plasma coating (e.g., plasma spraying) a coating material (e.g., Ytrria based material) onto the surface of the gas distribution plate at block 1206 as illustrated in FIG. 2B. In an embodiment, the coating material is plasma sprayed at an angle of approximately 90 degrees with respect to the surface of the gas distribution plate. A portion of the coating material may be optionally removed (e.g., grind) from the surface to reduce a thickness of the coating material. The method includes forming (e.g., UV laser drilling, gas hole drilling, mechanical machining) a second set of through-holes in the coating material such that the through-holes are aligned with the first-set of through-holes at block 1208. The method includes removing (e.g., surface grinding) a portion of the coating material from the surface to reduce a thickness of the coating material at block 1210. The surface is cleaned at block 1212.

In the following description, numerous details are set forth. It will be apparent, however, to one skilled in the art, that the present invention may be practiced without these specific details. In some instances, well-known structures and devices are shown in block diagram form, rather than in detail, in order to avoid obscuring the present invention. It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A gas distribution showerhead assembly for use within a semiconductor processing chamber, comprising:
a gas distribution plate having a first set of through-holes for delivering processing gases into the semiconductor processing chamber; and
a coating material that is sprayed onto the gas distribution plate, wherein the coating material has a second set of through-holes aligned with the first set of through-holes for delivering processing gases into the semiconductor processing chamber.

2. The gas distribution showerhead assembly of claim 1, wherein the coating material is a plasma spray coating.

3. The gas distribution showerhead assembly of claim 2, wherein the coating material comprises Ytrria.

4. The gas distribution showerhead assembly of claim 1, wherein the coating material comprises at least one of the following materials or combinations of materials:
YAG, Y₂O₃/2OZrO₂, Y₂O₃, Al₂O₃/YAG, an advanced coating material, Y₂O₃/ZrO₂/Nb₂O₅, ZrO₂/3Y₂O₃, and Y₂O₃/ZrO₂/HfO₂.

5. The gas distribution showerhead assembly of claim 4, wherein the advanced coating material comprises YtO3, AlO3, and ZrO3.

6. The gas distribution showerhead assembly of claim 1, wherein the first set of through-holes has a diameter of approximately 0.070 inches to 0.090 inches.

7. The gas distribution showerhead assembly of claim 5, wherein the second set of through-holes has a diameter of approximately 0.010 inches to 0.030 inches.

8. The gas distribution showerhead assembly of claim 1, wherein a thickness of the coating material is approximately 0.020 inches to 0.030 inches.

9. The gas distribution showerhead assembly of claim 1, wherein the gas distribution plate has a thickness of approximately 0.038 inches to 0.050 inches.

10. The gas distribution showerhead assembly of claim 5, wherein two of the second set of through-holes are aligned with each through-hole of the first set of through-holes.

11. A method of fabricating a gas distribution showerhead assembly, comprising:
providing a gas distribution plate having a first set of through-holes for delivering processing gases into a semiconductor processing chamber; and
plasma spraying a coating material onto the gas distribution plate.

12. The method of claim 11, further comprising:
removing a portion of the coating material to reduce a thickness of the coating material.

13. The method of claim 11, further comprising:
forming a second set of through-holes in the coating material such that the through-holes are aligned with the first-set of through-holes.

14. The method of claim 11, wherein the coating material comprises Ytrria.

15. The method of claim 11, wherein the coating material comprises at least one of the following materials or combinations of materials:
YAG, Y₂O₃/2OZrO₂, Y₂O₃, Al₂O₃/YAG, an advanced coating material, Y₂O₃/ZrO₂/Nb₂O₅, ZrO₂/3Y₂O₃, and Y₂O₃/ZrO₂/HfO₂.

16. The method of claim 11, wherein the advanced coating material comprises YtO3, AlO3, and ZrO3.

17. The method of claim 11, wherein the first set of through-holes has a diameter of approximately 0.070 inches to 0.090 inches and the second set of through-holes has a diameter of approximately 0.010 inches to 0.030 inches.

18. A semiconductor processing chamber, comprising:
a showerhead assembly that comprises
a gas distribution plate having a first set of through-holes for delivering processing gases into the semiconductor processing chamber; and
a coating material that is sprayed onto the gas distribution plate, wherein the coating material has a second set of through-holes aligned with the first set of through-holes for delivering processing gases into the semiconductor processing chamber; and
a RF power source coupled to the showerhead assembly, the RF power source to bias the showerhead assembly.

19. The semiconductor processing chamber of claim 18, wherein the coating material is a plasma spray coating.

20. The semiconductor processing chamber of claim 19, wherein the coating material comprises at least one of the following materials or combinations of materials:
Ytrria, YAG, Y₂O₃/2OZrO₂, Y₂O₃, Al₂O₃/YAG, an advanced coating material, Y₂O₃/ZrO₂/Nb₂O₅, ZrO₂/3Y₂O₃, and Y₂O₃/ZrO₂/HfO₂.
